(19) United States
(12) Patent Application Publication
(10) Pub. No.: US 2025/0271476 A1
(43) Pub. Date: Aug. 28, 2025

(54) SPECTROSCOPY BASED ON SELECTIVE FREQUENCY BIN

(71) Applicant: TEXAS INSTRUMENTS INCORPORATED, Dallas, TX (US)

(72) Inventors: Bassem Ibrahim, Allen, TX (US); Dave Magee, Allen, TX (US)

(21) Appl. No.: 18/588,631

(22) Filed: Feb. 27, 2024

(51) Int. Cl. G01R 23/16

(52) U.S. Cl. CPC G01R 23/16

(57) ABSTRACT

An apparatus includes an analog-to-digital converter (ADC) circuit having an analog input, and a digital output, the ADC circuit configured to sample a first signal at the analog input at a sampling frequency and provide a second signal representing samples of the first signal at the digital output. The apparatus further includes a processing circuit having a processing input, a frequency bin width input, a frequency bin index input, and a processing output, the processing input coupled to the digital output, and the processing circuit configured to provide a third signal as a Fourier transform representation of at least a part of the samples at the processing output based on states of the frequency bin width input and the frequency bin index input.

### BACKGROUND

Spectroscopy is commonly used in several fields such as electrical spectroscopy, mechanical spectroscopy, optical spectroscopy and electrochemical impedance spectroscopy. One way of performing spectroscopy is based on analyzing the results of a Fourier transform, such as a discrete Fourier transform (DFT) of a signal, to analyze the properties of the signal in the frequency domain. For example, an excitation signal may cause a device under test to generate a response signal. The response signal can be sampled, and the samples can be converted from the time domain to the frequency domain using a DFT. An N-point DFT converts N number of time-domain samples into N number of DFT values, where each DFT value is a complex-valued, frequency domain representation of a signal at a particular frequency. A DFT may be implemented using a fast Fourier transform (FFT) where the FFT computes many DFT values in parallel. A FFT results in complex multiplications and additions as well as requiring a large amount of memory usage to store all of the complex DFT values. The complexity and memory usage involved in spectroscopy can be exacerbated in applications where a large number of DFT values are computed.

### SUMMARY

In an example, an apparatus includes an analog-to-digital converter (ADC) circuit and a processing circuit. The ADC has an analog input, and a digital output. The ADC circuit is configured to sample a first signal at the analog input at a sampling frequency and provide a second signal representing samples of the first signal at the digital output. The processing circuit has a processing input, a frequency bin width input, a frequency bin index input, and a processing output. The processing input is coupled to the digital output, and the processing circuit is configured to provide a third signal as a Fourier transform representation of at least a part of the samples at the processing output based on states of the frequency bin width input and the frequency bin index input.

In an example, a system includes an excitation device having a first device under test (DUT) terminal. The system also includes a sensing device having a second DUT terminal. The system further includes a controller coupled to the excitation device and to the sensing device. The controller is configured to set a frequency of the excitation device. The controller is further configured to cause the excitation device to provide an excitation signal at the frequency at the first DUT terminal. The controller is additionally configured to transmit a frequency bin width signal, which can represent or can be based on the sampling frequency of the sensing device and the number of DFT values, and a frequency bin index signal to the sensing device, the frequency bin index signal being based on the frequency. The sensing device includes an analog-to-digital converter (ADC) circuit having an analog input and a digital output, the analog input coupled to the second DUT terminal. The ADC circuit is configured to sample a first signal at the analog input at a sampling frequency and provide a second signal representing samples of the first signal at the digital output. The sensing device further includes a processing circuit having a processing input, a frequency bin width input, a frequency bin index input, and a processing output, the processing input coupled to the digital output. The processing circuit is configured to provide a third signal as a Fourier transform representation of at least a part of the samples at the processing output based on the frequency bin width signal and the frequency bin index signal.

In an example, a method includes sampling a first signal at a sampling frequency. The method further includes providing a second signal representing samples of the first signal. In an example, the method also includes providing a third signal as a Fourier transform representation of a part of the samples based on states of a frequency bin width input and a frequency bin index input, wherein the at least the part of the samples is a first part of the samples. The method additionally includes receiving a first frequency bin width signal indicating a first frequency bin width. Additionally, the method includes receiving a second frequency bin width signal indicating a second frequency bin width. The method also includes receiving a first frequency bin index signal indicating a first frequency bin index. Furthermore, the method includes receiving a second frequency bin index signal indicating a second frequency bin index. The method additionally includes determining a frequency bin index offset based on the first frequency bin width signal, the first frequency bin index signal, and a second part of the samples. In an example, the method further includes determining a corrected frequency bin index based on the second frequency bin index and the frequency bin index offset. Moreover, the method further includes providing the third signal as the Fourier transform representation of the first part of the samples at a frequency bin having the corrected frequency bin index and the second frequency bin width.

### BRIEF DESCRIPTION OF THE DRAWINGS

FIG. 1 is a schematic diagram of system for analyzing signal in frequency domain using a selective frequency bin, in an example.

FIG. 2 is a graph illustrating an FFT operation, in an example.

FIG. 3 is a schematic diagram of a DFT unit that performs a selective frequency bin DFT operation, in an example.

FIG. 4 is a graph illustrating a frequency bin offset, in an example.

FIG. 5 is a schematic diagram of a system for analyzing a signal in the frequency domain using a selective frequency with frequency bin offset correction, in an example.

FIG. 6 is a graph illustrating a frequency bin offset estimation operation, in an example.

FIG. 7 is a flowchart illustrating a frequency bin offset estimation and frequency update operation, in an example.

FIG. 8 is graph illustrating an iterative frequency bin offset estimation operation, in an example.

FIG. 9 is a flowchart of performing a spectroscopy analysis, in an example.

FIG. 10 is a schematic of an example processor that can implement part of the system of FIGS. 1, 3, 5, and 7-9, in an example.

### DETAILED DESCRIPTION

The same reference numbers or other reference designators are used in the drawings to designate the same or similar (either by function and/or structure) features.

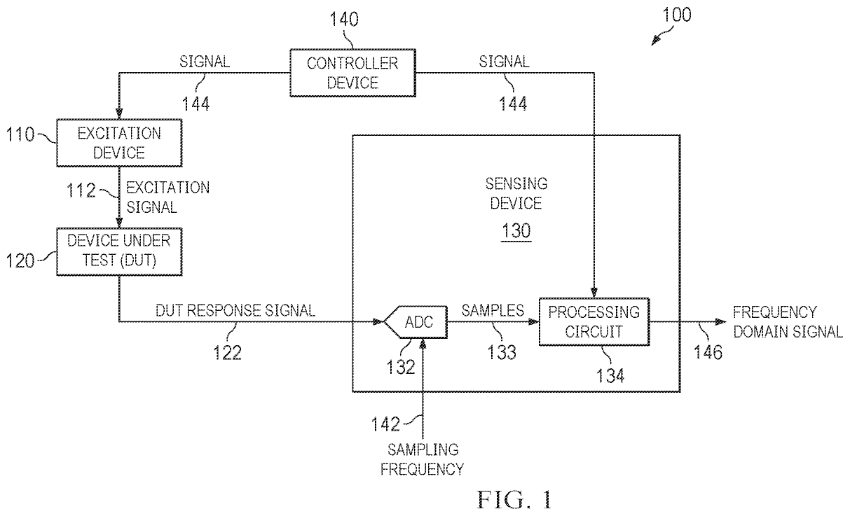

FIG. 1 is a schematic diagram of system 100 for analyzing a signal in the frequency domain using a selective frequency bin DFT operation, in an example. The system 100 includes an excitation device 110 coupled to a device under test (DUT) 120 that is coupled to a sensing device 130. The system 100 further includes a controller device 140 that is coupled to the excitation device 110 and to the sensing device 130. The sensing device 130 includes an analog-to-digital converter (ADC) 132 that is coupled to a processing circuit 134. Processing circuit 134 can include various modules, which can be circuit modules (e.g., part of an application specific integrated circuit (ASIC), a programmable logic array circuit), or software modules executable on a controller. The ADC 132 has an analog input and a digital output such that the analog signal, e.g., DUT response signal 122, is received and converted into the discrete-time domain samples, e.g., samples 133, and output from the digital output.

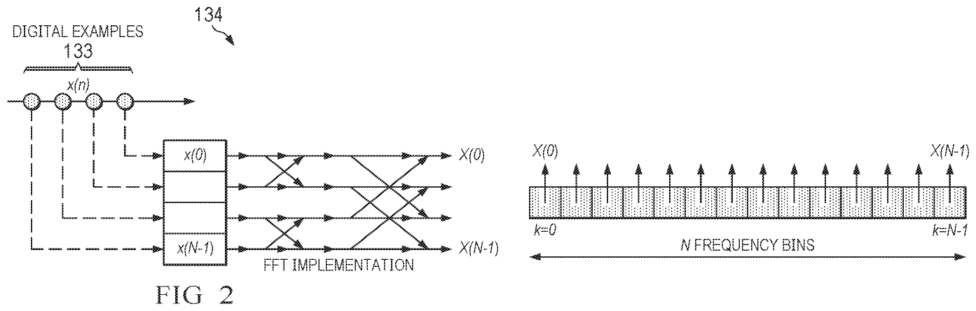

In an example, the DUT 120 is a target device that is analyzed in the frequency domain using a spectroscopy method, such as impedance spectroscopy. Examples of DUT 120 for which an impedance spectroscopy analysis is performed can include a charge storage device (e.g., a battery, a capacitor, a super capacitor, etc.), a motor, a sensor, etc. The excitation device 110 applies an excitation signal, e.g., electrical, mechanical, optical, etc., to the DUT 120 in order for the sensing device 130 to measure a DUT response signal 122 from the DUT 120. The DUT response signal 122 may be converted to a voltage or current signal, as desired, by an analog front-end (not shown). The DUT response signal 112 is sampled at sampling frequency 142, e.g., fₛ, by the ADC 132 to convert the received analog signal into samples, e.g., samples 133, that is subsequently processed by the processing circuit 134. The processing circuit 134 of the sensing device 130 may include a DFT module that is implemented using a FFT, as shown in FIG. 2. In an example, the frequency components of the signal calculated by the DFT module may be:

$$X [ k ] = {\sum }_{n = 0}^{N - 1} x [ n ] \cdot {e}^{( - j \frac{2 π k}{N} ) n} \qquad ( Equation 1 )$$

In Equation 1, N is the number of DFT frequency bins and k is the frequency bin index from 0 to N−1. A frequency component is computed for each frequency bin associated with a particular frequency bin index k.

The number of complex multiplications for the DFT may be represented as O(N²), which illustrates that the complexity increases quadratically as N increases. The FFT computes many DFT components in parallel, as illustrated in FIG. 2, for the samples 133, which includes (N/2) log₂ (N) complex multiplications and N log₂ (N) complex additions. In certain applications, N is large. For example, in electrochemical impedance spectroscopy, the frequency may range from 0.025 Hz to 5 kHz to monitor all chemical reactions inside the battery. For a Nyquist ADC sampling rate of 10 kHz and a minimum frequency resolution of 0.025 Hz, 400,000 DFT values may be computed, which is process intensive as well as using a large amount of memory.

In some examples, to reduce the computation and the amount of memory usage, the controller device 140 can perform a selective frequency bin DFT operation, in which only the frequency components of a reduced number of frequency bins are computed. The frequency bins are selected based on their frequency bin index corresponding to a set of frequencies, such as the frequencies of the excitation signals. Such arrangements can reduce the number of frequency components computed, yet those frequency components can provide accurate representation of the response of the DUT to the excitation signals to support the spectroscopy analysis.

Specifically, to support the selective frequency bin DFT operation, the controller device 140 transmits a signal 144 to the excitation device 110 and the sensing device 130. The signal 144 indicates the frequency bin width (e.g., a frequency width for each bin) and the frequency bin index. In other words, a particular frequency bin or bins are selected by the controller device 140. Thus, the controller device 140 controls the excitation by the excitation device 110 and further controls the sensing device 130 by sending configuration parameters, e.g., frequency bin index, frequency bin width, etc., and control commands.

In response to receiving the signal 144, the excitation device 110 generates an excitation signal 112 at the needed frequency components by the sensing device 130. Accordingly, the excitation signal 112 generated by the excitation device 110 is aligned with the DFT module of the processing circuit 134 at the specified frequency bin, thereby reducing spectral leakage, increasing signal to noise ratio, and reducing memory usage. For example, the controller device 140 selecting a frequency bin results in computations for the selected bin instead of all frequencies, which occurs in a traditional FFT. In the electrochemical impedance spectroscopy, for the example provided above, 50 frequency components are used for the entire frequency range of 0.025 Hz to 5 kHz in order to estimate the battery parameters instead of using 400,000 frequency components. In an example, the excitation device 110 generates the excitation signal 112 at the frequencies of

$${f}_{i} = \frac{{k}_{i} {f}_{s}}{N}$$

based on the frequency bin index and the frequency bin width f_{bin}, where

$${f}_{bin} = \frac{{f}_{s}}{N} ,$$

i is an index for a particular frequency bin, fₛ is the sampling frequency, and N is the number of frequency bins for the DFT module.

In an example, the processing circuit 134 includes a processing input that receives the samples 133. The processing circuit 134 also includes a frequency bin width input and a frequency bin index input for receiving the signal 144. The processing circuit 134 process the samples 133 using the configuration parameters received as signal 144 and provides a signal, e.g., frequency signal 146, that is a Fourier transform representation of at least a part of the samples 133, as shown by the equation below. The DFT is performed on a subset of frequencies instead of the entire frequency components. In an example, the DFT calculation by the processing circuit 134 based on the signal 144, for a selective frequency bin DFT module, is shown below:

$$X [ {k}_{i} ] = {\sum }_{n = 0}^{N - 1} x [ n ] \cdot {e}^{( - j \frac{2 π {k}_{i}}{N} ) n} \qquad ( Equation 2 )$$

The frequency domain signal 146 is output from the processing circuit 134 via its digital output. The frequency domain signal 146 represents properties of the DUT 120 at particular frequencies in the frequency domain.

FIG. 3 is a schematic diagram of a DFT module that performs a selective frequency bin DFT operation, in an example as shown. The processing circuit 134 may be implemented as a selective frequency bin DFT module as shown in FIG. 3, for illustrative purposes that should not be construed as limiting the scope. The samples 133 are received, along with coefficients 302 and operated on by a multiplier 310. The result is sent to an adder 320 where the result is summed with previous results via the delay element 330 until the frequency domain signal 146 is generated and output from the sensing device 130. FIG. 3 is illustrated as one implementation of a selective frequency bin DFT module where each individual frequency component is computed serially using a multiplier 310 and an adder 320, as illustrated. A coefficient for each frequency component may be generated by a coefficient generator at each sample instant n to multiply each sample 133, e.g., x[n], by their corresponding coefficient. Accordingly, the DFT operation may be implemented efficiently for a small number of frequency components (e.g., since a subset of frequency bins rather than all frequency bins are computed) and a large number of DFT points. As such, the complexity is reduced by having only M number of multiplications and M−1 number of additions associated with the selected frequency bin, as opposed to the conventional DFT system. Moreover, the DFT computation is performed serially on the input time-domain samples, thereby eliminating the need for a large memory buffer.

As described above, the frequency components computed using a selective frequency bin DFT module can provide an accurate representation of the response of the DUT to the excitation signals to support the spectroscopy analysis if the selected frequency bins correspond to the frequencies of the excitation signals. But if there is a frequency bin offset between the selected frequency bins and the frequencies of the excitation signals, the output of the selective frequency bin DFT module may not accurately represent the response of the DUT.

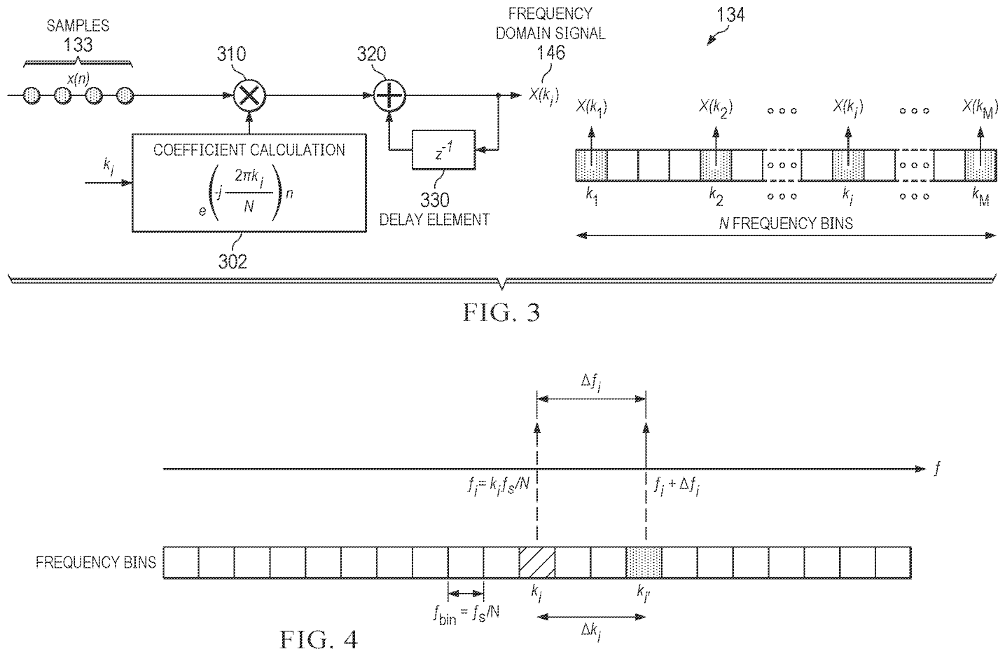

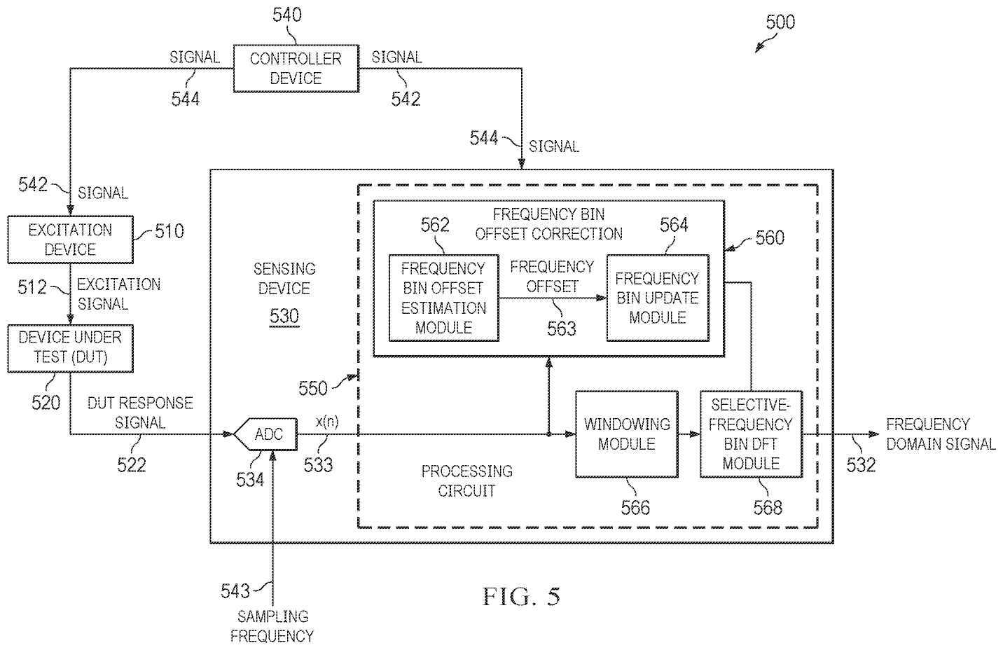

FIG. 4 is a graph illustrating a frequency bin offset, in an example. Often times, separate devices are used as the excitation device 110 and the sensing device 130 with each having its own local clock. It is not uncommon for the local clock of different devices to drift with respect to one another, causing an offset. For example, in FIG. 4, the controller device 140 may cause the excitation device 110 to generate an excitation signal 112 based on a selected frequency bin, e.g., kᵢ, having a particular frequency bin width with the excitation frequency at, e.g.

$${f}_{i} = \frac{{k}_{i} {f}_{s}}{N} .$$

The controller device 140 communicates the same parameters to the sensing device 130, e.g., signal 144, and as such the sensing device 130 expects the signal at excitation frequency

$${f}_{i} = \frac{{k}_{i} {f}_{s}}{N} .$$

However, the frequency may have drifted to fᵢ+Δfᵢ, where Δfᵢ is the frequency bin offset resulting from frequency drift between the sensing device 130 and the excitation device 110. If the frequency bin offset is larger than the frequency bin width (e.g., f_{bin}=fₛ/N), as illustrated in FIG. 4, then the excitation signal 112 does not appear at the expected frequency bin kᵢ and instead may appear at a different frequency bin, e.g., kᵢ′. Accordingly, any measurement and/or computation by the sensing device 130 at the expected frequency bin index, e.g., kᵢ, results in a DFT value that is zero or close to because all of the signal energy is now at bin kᵢ′ instead of kᵢ.

FIG. 5 is a schematic diagram of a system 500 for analyzing a signal in the frequency domain using a selective frequency with frequency bin offset correction, in an example. The system 500 can determine the amount of frequency shift and correct and update the frequency bin index to address the issue shown in FIG. 4. The system 500 includes an excitation device 510 coupled to a DUT 520 that is coupled to a sensing device 530. The system 500 further includes a controller device 540 that is coupled to the excitation device 510 and to the sensing device 530. The sensing device 530 includes an ADC 534 that is coupled to a processing circuit 550. Processing circuit 550 can include various modules, which can be circuit modules (e.g., part of an application specific integrated circuit (ASIC), a programmable logic array circuit), or software modules executable on a controller.

The ADC 534 has an analog input and a digital output such that analog signal, e.g., DUT response signal 522, is received and converted into the discrete time domain, e.g., samples 133, and output from the digital output. The processing circuit may include a frequency bin offset correction module 560 that is coupled to a windowing module 566 and a selective frequency bin DFT module 568 (all of which are described in greater detail below). The use of the selective frequency bin DFT module 568 is for illustration purposes and should not be construed as limiting the scope. For example, a multi-bin DFT module may be used where the number of bins is less than the total number of frequency components if a full DFT was performed.

In an example, the DUT 520 is a target device, e.g., a battery in electro-chemical impedance spectroscopy, human tissue in infrared spectroscopy, etc., that is analyzed in the frequency domain using a spectroscopy method. The excitation device 510 applies an excitation signal, e.g., electrical, mechanical, optical, etc., to the DUT 520 in order for the sensing device 530 to measure a DUT response signal 522 from the DUT 520. The DUT response signal 522 may be converted to a voltage or current signal, as desired, by an analog front-end (not shown). The DUT response signal 512 is sampled at a sampling frequency 543, e.g., fₛ, by the ADC 534 to convert the received analog signal to the discrete time domain samples, e.g., samples 533, that are subsequently processed by the processing circuit 550. The processing circuit 550 of the sensing device 530 may include a selective frequency bin DFT module 568, as shown in FIG. 3.

In order to reduce the number of frequency domain components (N), the number of computations and the amount of memory usage, the controller device 540 transmits a signal 542 to the sensing device 530. The signal 542 indicates the frequency bin width (e.g., a frequency width of each bin) and the frequency bin index. In other words, a particular frequency bin or bins are selected by the controller device 540. Thus, the controller device 540 controls the excitation by the excitation device 510 and further controls the sensing device 530 by sending configuration parameters, e.g., frequency bin index, and frequency bin width, which can represent or based on the sampling frequency of the sensing device and the number of DFT values, and control commands.

In response to receiving the signal 542, the excitation device 510 generates an excitation signal 512 at one or more excitation frequencies

$${f}_{i} = \frac{{k}_{i} {f}_{s}}{N} ,$$

where i is an index for a particular frequency bin, fₛ is the sampling frequency, and N is the number of frequency bins for the DFT module. Excitation device 510 can compute the excitation frequency based on the frequency bin width fₛ/N and frequency bin index kᵢ from signal 542. Accordingly, the excitation signal 512 generated by the excitation device 510 is aligned with the DFT module of the processing circuit 550 at the specified frequency bin, thereby reducing spectral leakage, increasing signal to noise ratio, and reducing memory usage. For example, the controller device 540 selecting a frequency bin results in computations for the selected bin instead of all frequencies. In the electrochemical impedance spectroscopy, for the example provided above, 50 frequency components are used for the entire frequency range of 0.025 Hz to 5 kHz in order to estimate the battery parameters instead of using 400,000 frequency components in a full DFT implementation.

In an example, the processing circuit 550 includes a processing input that receives the samples 533. The processing circuit 550 also includes a frequency bin width input and a frequency bin index input for receiving the signal 542. The processing circuit 550 process the samples 533 using the configuration parameters received as signal 542 and forms a signal, e.g., a frequency domain signal 532, that is a Fourier transform representation of at least a part of the samples 533. In other words, the DFT is performed on a subset of frequencies instead of the entire frequency components. In an example, the DFT computation by the processing circuit 550 based on the signal 542, for a selective frequency DFT module, is based on Equation 2 described above.

The frequency domain signal 532 is output from the processing circuit 550 via its digital output. The frequency domain signal 532 is indicative of analysis of properties of the DUT 520 in frequency domain.

As described above with respect to FIG. 4, a frequency bin offset between the excitation device 510 and the sensing device 530 may cause the excitation signal 512 to not appear at the expected frequency bin kᵢ and instead may appear at a different frequency bin, e.g., kᵢ′. Accordingly, any measurement and/or computation by the sensing device 530 at the expected frequency bin, e.g., kᵢ, results in a DFT value that is zero or close to zero because all of the signal energy is now at bin kᵢ′ instead of kᵢ. Accordingly, the controller device 540 may cause the sensing device 530 to perform a frequency bin offset calculation and a frequency update. The controller device 540 expands the frequency bin width to capture the frequency content that has moved outside of the expected frequency bin index due to frequency drift between the excitation device and the sensing device. For example, the controller device 540 may expand the frequency bin width to three times the original size such that the new bin width, kᵢ′, would cover frequency bin index kᵢ, kᵢ+1, kᵢ+2. As such, the frequency content that could have been lost due to frequency bin offset can now captured in the new frequency bin for processing.

In order to expand the frequency bin width, the controller device 540 sends a signal 544 to the excitation device 510 and further to the sensing device 530. The signal 544 indicates the offset estimation parameters, e.g., estimation frequency bin width (e.g., an expanded frequency width for each bin) and the estimation frequency bin index. The controller device 540 determines a particular frequency bin index, e.g., kₑₛₜ, to be used by the excitation device 510 and the sensing device 530. In an example, f_{bin_est}>2*Δfₑₛₜ is the frequency bin width to be used during frequency bin offset estimation and where Δfₑₛₜ is the largest frequency drift expected, so that that the frequency bin offset estimation frequency fₑₛt can appear within the target frequency bin kₑₛₜ. The controller device 540 may therefore determine Nₑₛₜ, which may be the number of DFT points based on the biggest expected frequency drift, and may determine

$${f}_{bin \_ est} = \frac{{f}_{s}}{{N}_{est}}$$

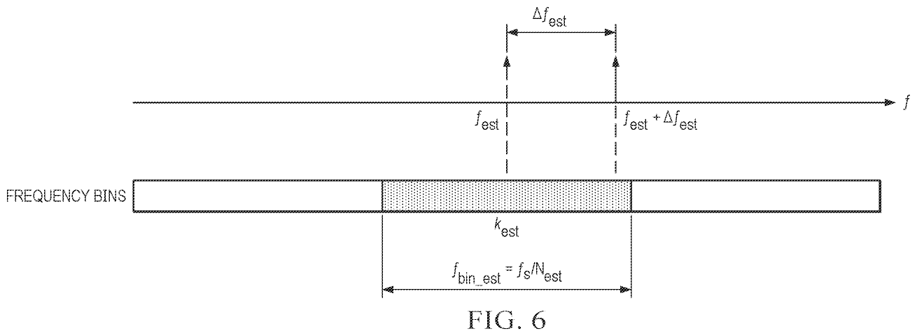

(in order to extend the frequency bin width). Accordingly, changing the number of DFT points changes the frequency bin width. As such, the frequency bin offset estimation frequency fₑₛₜ is aligned with the frequency bin index kₑₛₜ such that fₑₛₜ=kₑₛₜ. f_{bin_est}. The signal 544 transmits the frequency bin offset estimation parameters, e.g., estimation frequency bin index (kₑₛₜ) and estimation frequency bin width (f_{bin_est}), or estimation frequency bin index (kₑₛₜ) and the number of DFT values (Nₑₛₜ) to be used such that the excitation device 510 and/or the sensing device 530 can each compute the frequency bin width. Expansion of the frequency bin width for frequency bin offset estimation is shown in FIG. 6. Increasing the frequency bin width results in the frequency bin offset to become a fraction of a known frequency bin width and can be estimated from the phase difference between two or more DFT measurements, which will be described below.

The excitation device 510 therefore receives the signal 544 that indicates the frequency bin offset estimation parameters, e.g., frequency bin index (kₑₛₜ) and frequency bin width (f_{bin_est}), or estimation frequency bin index (kₑₛₜ) and the number of DFT values (Nₑₛₜ) that can be used to compute the frequency bin width when the sampling frequency is known. The excitation device 510 generates excitation signal 512 similar to before and causes the DUT 520 to generate a DUT response signal 522 similar to before but with respect to the new excitation signal generated based on the offset estimation parameters. For example, the excitation device 510 generates and transmits the excitation signal 512 at fₑₛₜ that corresponds to the frequency bin index kₑₛₜ for a time duration that is at least 2Nₑₛₜ samples. The DUT response signal 522 may be converted to voltage or current, as desired, by an analog front-end (not shown) and subsequently converted to discrete time-domain by the ADC 534 using the sampling frequency 543. The samples (x(n)) 533 are output from the digital output of the ADC 534 to the processing input of the processing circuit 550, e.g., to the frequency bin offset correction module 560 and further to the windowing module 566.

The frequency bin offset correction 560 of the processing circuit 550 within the sensing device 530 may include a frequency bin offset estimation module 562 and a frequency bin update module 564. The frequency bin offset correction 560 may also receive the signal 544 as its input, e.g., frequency bin width input, frequency bin index input, etc. To determine the frequency bin offset estimation, the frequency bin offset estimation module 562 in an example, uses the time shift of continuous time Fourier Transform due to a time shift tO is shown below:

$$x ( t - {t}_{0} ) = {e}^{- ( {wt}_{0} )} X ( j ω ) \qquad ( Equation 3 )$$

The controller device 540 causes the processing circuit 550 to run two DFT windows, e.g., back-to-back, in order to estimate the frequency bin offset Δfₑₛₜ. The time shift

$${t}_{0} = \frac{{N}_{est}}{{f}_{s}}$$

for the time duration of one DFT window with Nₑₛₜ number of DFT points. The DFT windows size are chosen such that each window does not contain complete cycles of DUT response signal 122, which allows the back-to-back DFT windows to capture DUT response signals having different starting phases. The frequency ω is calculated as 2π(fₑₛₜ+Δfₑₛₜ) for a frequency bin offset estimation signal at frequency fₑₛₜ with frequency bin offset Δfₑₛₜ. As such, the phase shift between the two DFT windows may be represented as:

$$Δφ = ω {t}_{o} = \frac{2 π ( {f}_{est} + Δ {f}_{est} ) {N}_{est}}{{f}_{s}} \qquad ( Equation 4 )$$

In Equation 4, because fₑₛₜ=kₑₛₜf_{bin_est} and

$${f}_{bin \_ est} = \frac{{f}_{s}}{{N}_{est}}$$

then

$${f}_{est} = {k}_{est} \frac{{f}_{s}}{{N}_{e s t}} , and \frac{2 π {f}_{e s t} {N}_{e s t}}{{f}_{s}} = 2 π {k}_{est} .$$

Since kₑₛₜ is an integer, the phase shift Δφ can be calculated as follows:

$$Δφ = \frac{2 π Δ {f}_{e s t} {N}_{e s t}}{{f}_{s}} \qquad ( Equation 5 )$$

From Equations 4 and 5, the frequency bin offset Δfₑₛₜ can be determined as follows:

$$Δ {f}_{est} = \frac{Δφ {f}_{s}}{2 π {N}_{e s t}} \qquad ( Equation 6 )$$

In other words, the phase shift between the two DFT windows is used by the frequency bin offset estimation module 562 to determine the frequency bin offset, as described above. The frequency bin offset 563 signal as determined by the frequency bin offset estimation module 562 is output to the frequency bin update module 564 where the corrected frequency bin index is generated, e.g., k_{corr_i}, for each measurement frequency bin kᵢ is calculated. The signal associated with the corrected frequency bin index is transmitted to the selective frequency bin DFT module 568 to compute the frequency domain signal 532 (Fourier transform representation of a part of the samples at frequency bin with the corrected frequency bin index and frequency bin width).

According to an example, in frequency bin offset estimation, the windowing module 566 receives the samples x(n) 533 and selects at least two parts of the samples 533, e.g., a first and a second windows. The selected data associated with each window is sent to the selective frequency bin DFT module 568 to calculate a DFT output at frequency bin index kₑₛₜ and with Nₑₛₜ number of DFT points. The selective frequency bin DFT module 568 generates one DFT output for each window, e.g., X1 and X2. The DFT output is sent to the frequency bin offset correction 560 where the phase for each DFT output is determined. For example, the phase, e.g., φ₁ and φ₂, for the DFT output X1 and X2 may be determined as:

$${φ}_{1} = {tan}^{- 1} \frac{Im ( {X}_{1} [ {k}_{e s t} ] )}{Re ( {X}_{1} [ {k}_{e s t} ] )} and {φ}_{2} = {tan}^{- 1} \frac{Im ( {X}_{2} [ {k}_{e s t} ] )}{Re ( {X}_{2} [ {k}_{e s t} ] )} \qquad ( Equation 7 )$$

The frequency bin offset estimation module 562 may determine the phase difference, e.g., Δφ_{2π}=φ₂−φ₁. The phase difference may be from −2π to 2π and is converted to a range from −π to π according to the example algorithm below:

```
if Δφ_{2π} < − π
  Δφₙ = Δφ_{2π} + 2π
else if Δφ_{2π} > + π
  Δφₙ = Δφ_{2π} − 2π
else
  Δφₙ = Δφ_{2π}
```

According to one example, the process as described above, is repeated and an average may be taken to improve the accuracy of the phase estimation. As described above, the frequency bin offset Δfₑₛₜ is estimated by the frequency bin offset estimation module 562 based on the phase difference. For example, the frequency bin offset can be computed as follows:

$$Δ {f}_{est} = \frac{Δφ {f}_{s}}{2 π {N}_{e s t}} \qquad ( Equation 8 )$$

The signal 563 associated with frequency bin offset Δfₑₛₜ is sent to the frequency bin update module 564 in order to determine the corrected frequency bin index. The corrected frequency bin index is used to update the frequency in the sensing device 530 when performing the DFT operation. The frequency bin width during sensing is

$${f}_{bin} = \frac{{f}_{s}}{N} .$$

The frequency bin offset for a frequency bin index kᵢ represented as a frequency bin offset, as follows:

$$Δ {k}_{i} = round ( \frac{Δ {f}_{i}}{{f}_{b i n}} ) = round ( \frac{Δφ {k}_{i}}{2 π {k}_{e s t}} ) \qquad ( Equation 9 )$$

Moreover, because

$$Δ {f}_{i} = \frac{Δ {f}_{e s t}}{{f}_{e s t}} \cdot {k}_{i} \cdot \frac{{f}_{s}}{N} , {f}_{bin} = \frac{{f}_{s}}{N} and {f}_{est} = {k}_{est} \cdot \frac{{f}_{s}}{{N}_{e s t}} ,$$

the corrected frequency bin index k_{corr_i} is computed based on the phase difference Δφ as follows:

$${k}_{corr \_ i} = {k}_{i} + round ( \frac{Δφ \cdot {k}_{i}}{2 π \cdot {k}_{e s t}} ) \qquad ( Equation 10 )$$

The corrected frequency bin index, as determined by the frequency bin update module 564 is sent to the selective frequency-bin DFT module 568 such that the corrected frequency bin index can be used by the selective frequency bin DFT module 568 to accurately perform a DFT to generate the frequency domain signal 532. In other words, the controller device 540 may cause the excitation device 510 to generate the excitation signal 512. The DUT 520 generates the DUT response signal 522 in response to the excitation signal 512. The DUT response signal 522 is sampled by the ADC 534 and sent to the selective frequency bin DFT module 568 that uses the corrected frequency bin index to compute the DFT at the corrected frequency bin value, instead of computing the DFT at the frequency of the excitation signal.

In some examples, the frequency bin offset correction may be initiated or triggered by the controller device 540. In an example, the frequency bin offset correction may be initiated when the output of the selective frequency bin DFT module 568 is zero or close to zero that indicates that there has been a frequency bin offset that may have resulted in the frequency component signals ending up at a different frequency bin index than the one that was expected. The controller device 540 sends control signals and configuration parameters to the excitation device 510 and the sensing device 530. In frequency correction mode, the controller device 540 sends the frequency bin offset estimation parameters (kₑₛₜ, Nₑₛₜ) to the excitation device 510 and the sensing device 530. The control signals and the configuration parameters are used by the excitation device 510 to generate the estimation signal at frequency fₑₛₜ=kₑₛₜ·fₛ/Nₑₛₜ. The controller device also controls the sensing device 530 by causing it to initiate the frequency bin offset estimation algorithm. In one example, the sensing device 530 performs the estimation DFT for two, back-to-back time intervals and the phase estimation step to calculate the phase difference Δφ and frequency bin offset Δf. The determined phase difference and frequency bin offset is used by the selective frequency bin DFT module 568 to correct the frequency bin index, e.g., k_{corr_i}. As such, in operation, when the controller device 540 sends the measurement parameters (kᵢ, N) to the excitation device 510 and the sensing device 530. The excitation device 510 generates the excitation signal 512 and the sensing device 530 performs measurements of the DUT response signal 522 by performing DFT using the selective frequency bin DFT module 568 at the corrected frequency bin index k_{corr_i}. According to one example, additional measurements can be repeated using the same frequency bin offset estimation if the magnitude of the DFT output |X[k_{corr}_{ᵢ}] is greater than a minimum threshold Xₘᵢₙ. This condition indicates that the frequency bin offset variations are less than the measurement frequency bin and the estimated frequency bin offset is still valid for correct measurements. If the DFT output is less than the threshold, then a new frequency bin offset correction is required and the entire frequency bin offset correction flow is repeated.

Accordingly, the system 500 determines the frequency correction by estimating the frequency difference between the excitation frequency generated by the excitation device 510 and the measured frequency by the sensing device 530. The estimated frequency difference is used to correct and update the frequency and the frequency bin to be used by the sensing device 530 when a selective frequency bin DFT module 568 is used by the processing circuit 550 to reduce the number of frequency components, to reduce the amount of memory, and to reduce the amount of processing.

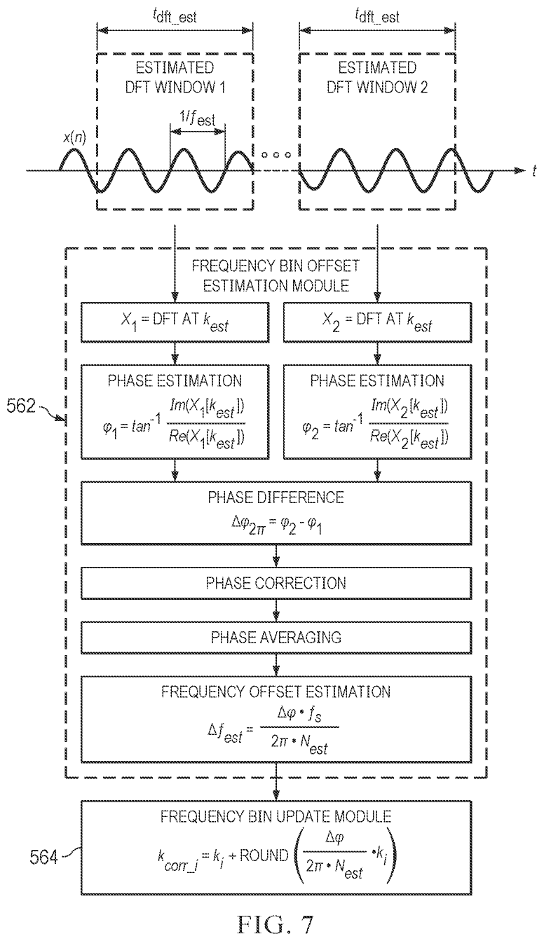

FIG. 7 is a flowchart illustrating a frequency bin offset estimation and frequency bin update operation, in an example. FIG. 7 shows two windows, windows 1 and 2 where window 1 is a first part of digital sample 533 and window 2 is a second part of the digital sample 533. Windows 1 and 2 may be selected by the windowing module 566 and the windows 1 and 2 may be two back-to-back windows. As described above with respect to FIG. 5, X₁ and X₂ are computed, the phase for each DFT output is estimated and a phase difference is determined. The phase correction is determined and in an example the process may be repeated, and the phase averaging may be performed for more accurate results. The frequency bin offset may be estimated using the phase difference and the corrected frequency bin index is determined.

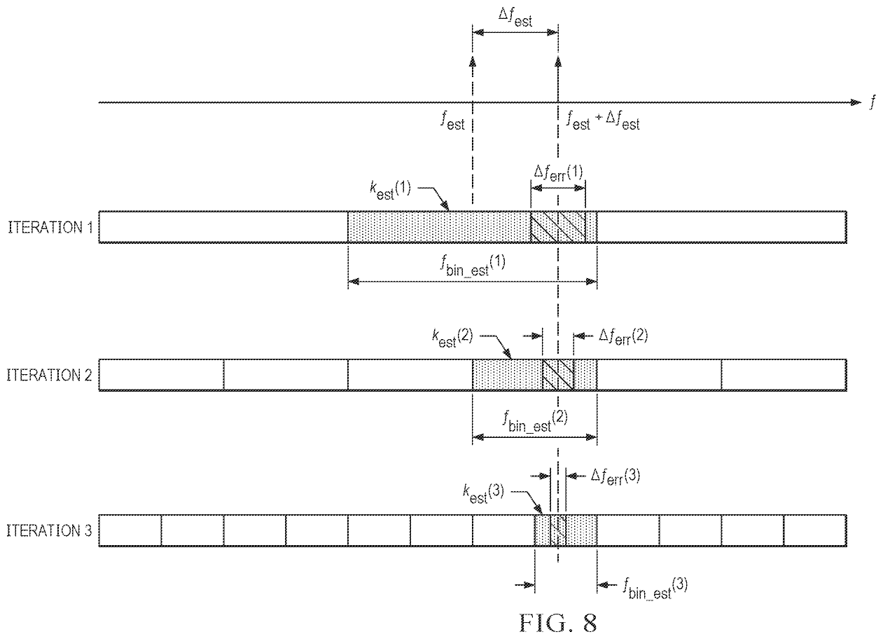

FIG. 8 is a graph illustrating an iterative frequency bin offset estimation operation, in an example. The accuracy of the frequency bin offset estimation depends on the noise in the sensed signals in addition to the estimation frequency bin width f_{bin_est} that is used in the DFT to estimate the signal phase. In other words, the narrower the frequency bin width, e.g., f_{bin_est}, the higher the accuracy of the frequency bin offset estimation. However, a narrower frequency bin width, f_{bin_est}, results in a smaller frequency bin offset range that can be detected. Accordingly, an iterative frequency bin offset estimation may be used to enable the system to start with a larger frequency bin width initially for frequency correction and to reduce the frequency bin width with each iteration until the frequency bin width reaches a desired value. In other words, a wide frequency bin width is initially used to increase the detectable frequency bin offset range but one that may result in a lower accuracy to detect the correct frequency bin index that corresponds to the desired impedance measurement frequency bin width. During each iteration, the frequency bin width is reduced, thereby improving the accuracy of the frequency bin offset estimate. Therefore, each of the following iterations will update the estimation DFT parameters kₑₛₜ and Nₑₛₜ in order to decrease the estimation DFT bin width f_{bin_est} successively, which will decrease the frequency bin offset estimation error as shown. The accuracy of frequency bin offset estimation improves as the number of iterations increases. As illustrated, in iteration 1, the frequency bin width is larger in comparison to subsequent iterations to ensure that the frequency drift resulting in the frequency components being placed in a different frequency bin index to be captured. The estimation from iteration 1 may be used in iteration 2 and the frequency bin width is reduced, and the process is repeated until the last iteration where the frequency bin width and the corrected frequency drift is determined for use by the selective frequency bin DFT module 568.

In an example, the iterative method starts at i=0 to initialize the estimation DFT parameters with an initial frequency bin k_{est_ini} and an initial number of estimation DFT points N_{est_ini} according to target fₑₛₜ as shown before. The iteration index is incremented, e.g., i+1, and the frequency bin index kₑₛₜ(i+1) is computed based on the estimated frequency and the frequency bin width of the previous iteration, the previous f_{bin_est}(i) is divided by two to center the estimated frequency in the new frequency bin. The frequency bin index kₑₛₜ(i+1) is shown as:

$${k}_{est} ( i + 1 ) = round ( \frac{2 {\hat{f}}_{est} ( i )}{{f}_{bin \_ est} ( i )} ) \qquad ( Equation 11 )$$

According to an example, the number of DFT points estimation and frequency bin width estimation at ith iteration is computed to be:

$${N}_{est} ( i + 1 ) = round ( \frac{{k}_{e s t} ( i + 1 ) {f}_{s}}{{\hat{f}}_{est} ( i )} ) \qquad ( Equation 12 )$$

$${f}_{bin \_ est} ( i + 1 ) = \frac{{f}_{s}}{{N}_{e s t} ( i + 1 )} \qquad ( Equation 13 )$$

The new frequency bin offset estimation at iteration i+1 may be computed based on the previously updated estimation DFT parameters. The new frequency bin offset estimation has less error in comparison to the one(s) computed in the previous iteration(s). The new frequency bin offset estimation is shown as:

$$Δ {f}_{est} ( i + 1 ) = \frac{Δφ ( i + 1 ) \cdot {f}_{s}}{2 π \cdot {N}_{e s t} ( i + 1 )} \qquad ( Equation 14 )$$

$${\hat{f}}_{est} ( i + 1 ) = {k}_{est} ( i + 1 ) {f}_{bin \_ est} ( i + 1 ) + Δ {f}_{est} ( i + 1 ) \qquad ( Equation 15 )$$

The iterations can be repeated until, for example, a target frequency bin offset estimation accuracy is achieved, and/or the number of iterations reach a desired value.

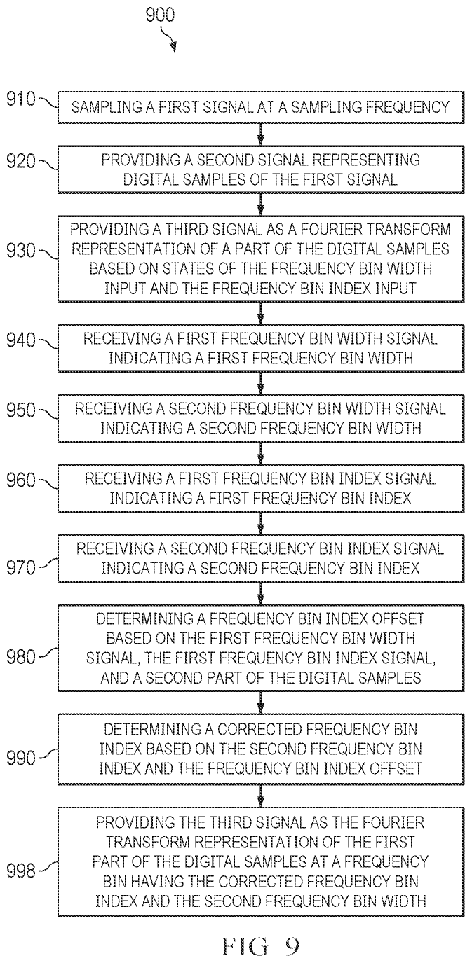

FIG. 9 is a flowchart of a method 900 for performing a frequency domain analysis of a signal using a selective frequency bin for a DFT module and performing frequency bin offset estimation and update, in an example. In operation 910, a first signal is sampled at a sampling frequency, as described in FIGS. 1 and 5. In operation 920, a second signal representing the samples of the first signal is provided, as described in FIGS. 1 and 5. In operation 930, a Fourier transform representation of a part of the digital sample is provided based on the states of the frequency bin width and the frequency bin index, as input, as described in FIGS. 1 and 5. In operation 940, a first frequency bin width signal indicating a first frequency bin width is received, as described in FIGS. 1 and 5 through 8. At step 950, a second frequency bin width signal indicating a second frequency bin width is received, as described in FIGS. 1 and 5 through 8. In operations 960 and 970, a first and a second frequency bin indices signal indicating the first and the second frequency bin indices are received respectively, as described in FIGS. 1 and 5 through 8. In operation 980, a frequency bin index offset is determined based on the first frequency bin width signal, the first frequency bin index signal, and a second part of the samples, as described in FIGS. 5 through 8. In operation 990, a corrected frequency bin index is determined based on the second frequency bin index and the frequency bin index offset, as described in FIGS. 5 through 8. In operation 998, the third signal is provided as the Fourier transform representation of the first part of the samples at a frequency bin having the corrected frequency bin index and the second frequency bin width, as described in FIGS. 5 through 8.

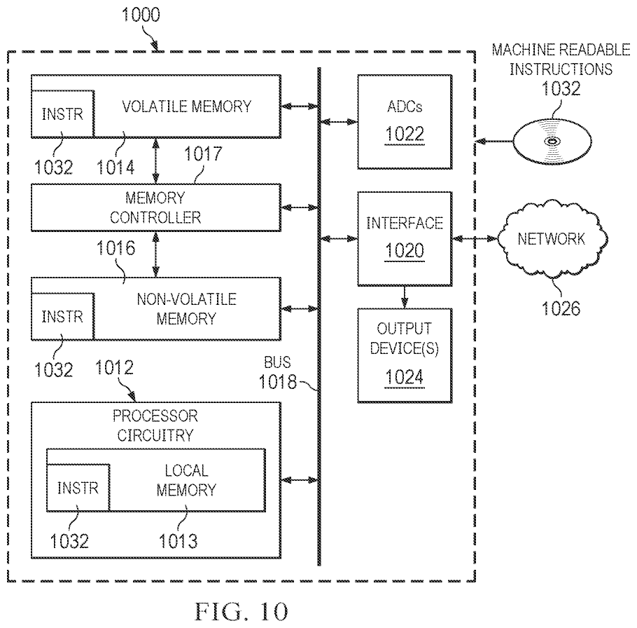

FIG. 10 is a block diagram of an example processor platform 1000 including processor circuitry structured to execute machine-readable instructions to implement the logic depicted in the examples of FIGS. 1 through 9. Processor platform 1000 of the illustrated example can include processor circuitry 1012. The processor circuitry 1012 of the illustrated example includes hardware. For example, processor circuitry 1012 can be implemented by one or more integrated circuits, logic circuits, FPGAs, microprocessors, Central Processing Units (CPUs), Graphical Processing Units (GPUs), Digital Signal Processors (DSPs), and/or microcontrollers from any desired family or manufacturer. Processor circuitry 1012 can be implemented by one or more semiconductor-based (e.g., silicon-based) devices. In this example, processor circuitry 1012 can implement the controllers 140 and processing circuit 134 of FIG. 1 and controller device 540, frequency bin offset correction module 560, frequency bin offset estimation module 562, frequency bin update module 564, windowing module 566, and selective frequency-bin DFT module 568 of FIGS. 5 and 7.

Processor circuitry 1012 of the illustrated example can include a local memory 1013 (e.g., a cache, registers, etc.). Processor circuitry 1012 of the illustrated example is in communication with a computer-readable storage device such as a main memory including a volatile memory 1014 and a non-volatile memory 1016 by a bus 1018. The volatile memory 1014 can be implemented by, for example, Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 10016 may be implemented by programmable read-only memory, flash memory and/or any other desired type of non-volatile memory device. Access to the main memory 1014, 1016 of the illustrated example can be controlled by a memory controller 1017.

The processor platform 1000 of the illustrated example also includes interface circuitry 1020. The interface circuitry 1020 may be implemented by hardware in accordance with any type of interface standard, such as an Inter-Integrated Circuit (I2C) interface, a Serial Peripheral Interface (SPI), an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input ADCs 1022 are connected to bus 1018. The ADCs 1022 can convert analog signals to digital signals for processing by the processor circuitry 1012. ADCs 1022 can represent ADCs 132 and 534.

One or more output devices 1024 can be connected to the interface circuitry 1020 of the illustrated example. The output device(s) 1024 can include circuits such as driver circuits.

Machine-readable instructions 1032 can be stored in volatile memory 1014 and/or non-volatile memory 1016. Upon execution by the processor circuitry 1012, the machine-readable instructions 1032 cause the processor platform 1000 to perform any or all of the functionality described herein attributed to the systems 100 and 500 and method 900.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Modifications are possible in the described embodiments, and other embodiments are possible, within the scope of the claims.

What is claimed is:

1. An apparatus comprising:
an analog-to-digital converter (ADC) circuit having an input and an output, the ADC circuit configured to sample a first signal at the input at a sampling frequency and provide a second signal representing samples of the first signal at the output; and
a processing circuit having a processing input, a frequency bin width input, a frequency bin index input, and a processing output, the processing input coupled to the output of the ADC circuit, and the processing circuit configured to provide a third signal as a Fourier transform representation of at least a part of the samples at the processing output based on states of the frequency bin width input and the frequency bin index input.

2. The apparatus of claim 1, wherein the at least the part of the samples is a first part of the samples, and the processing circuit is configured to:
receive a first frequency bin width signal indicating a first frequency bin width;
receive a second frequency bin width signal indicating a second frequency bin width;
receive a first frequency bin index signal indicating a first frequency bin index;
receive a second frequency bin index signal indicating a second frequency bin index;
determine a frequency bin index offset based on the first frequency bin width signal, the first frequency bin index signal, and a second part of the samples;
determine a corrected frequency bin index based on the second frequency bin index and the frequency bin index offset; and
provide the third signal as the Fourier transform representation of the first part of the samples at a frequency bin having the corrected frequency bin index and the second frequency bin width.

3. The apparatus of claim 2, wherein the Fourier transform representation is a first Fourier transform representation;
wherein the first frequency bin width signal indicates a first number of the samples to be included in determining one or more second Fourier transform representations of the second part of the samples; and
wherein the second frequency bin width signal indicates a second number of the samples to be included in determining the first Fourier transform representation of the first part of the samples.

4. The apparatus of claim 2, wherein the Fourier transform representation is a first Fourier transform representation;
wherein the first frequency bin width signal indicates a first sampling frequency at which the ADC samples the first signal to generate the second part of the samples; and
wherein the second frequency bin width signal indicates a second sampling frequency at which the ADC samples the first signal to generate the first part of the samples.

5. The apparatus of claim 2, wherein the Fourier transform representation is a first Fourier transform representation, and the processing circuit is configured to:
determine a second Fourier transform representation of a first subset of the second part of the samples at a frequency bin having the first frequency bin index and the first frequency bin width;
determine a first phase of the second Fourier transform representation;
determine a third Fourier transform representation of a second subset of the second part of the samples at the frequency bin;
determine a second phase of the third Fourier transform representation;
determine a difference between the first and second phases; and
determine the frequency bin index offset based on the difference and the second frequency bin index.

6. The apparatus of claim 5, wherein the first subset of second part of the samples is in a first time window, the second subset of the second part of the samples is in a second time window next to the first time window.

7. The apparatus of claim 5, wherein the processing circuit is configured to iteratively determine the frequency bin index offset by progressively reducing the first frequency bin width and updating the first frequency bin index.

8. A system comprising:
an excitation device having a first device under test (DUT) terminal;
a sensing device having a second DUT terminal and comprising:
an analog-to-digital converter (ADC) circuit having an input and an output, the input of the ADC circuit coupled to the second DUT terminal, the ADC circuit configured to sample a first signal at the input of the ADC circuit at a sampling frequency and provide a second signal representing samples of the first signal at the output of the ADC circuit; and
a processing circuit having a processing input, a frequency bin width input, a frequency bin index input, and a processing output, the processing input coupled to the output of the ADC circuit, and the processing circuit configured to provide a third signal as a Fourier transform representation of at least a part of the samples at the processing output based on a frequency bin width signal at the frequency bin width input and a frequency bin index signal at the frequency bin width input; and
a controller coupled to the excitation device and to the sensing device, the controller configured to:
set a frequency of the excitation device;
cause the excitation device to provide an excitation signal at the frequency at the first DUT terminal; and
transmit the frequency bin width signal and the frequency bin index signal to the sensing device, the frequency bin index signal being based on the frequency.

9. The system of claim 8, wherein the at least the part of the samples is a first part of the samples, and wherein the controller is configured to:
transmitting a fourth signal to the sensing device to initiate a frequency and a phase update on the sensing device based on the third signal;
transmit a first frequency bin width signal indicating a first frequency bin width to the sensing device;
transmit a first frequency bin index signal indicating a first frequency bin index to the sensing device;
transmit a second frequency bin width signal indicating a second frequency bin width; and
transmit a second frequency bin index signal indicating a second frequency bin index; and
wherein the processing circuit is configured to:
determine a frequency bin index offset based on the first frequency bin width signal, the first frequency bin index signal, and a second part of the samples;
determine a corrected frequency bin index based on the second frequency bin index and the frequency bin index offset; and
provide the third signal as the Fourier transform representation of the first part of the samples at a frequency bin having the corrected frequency bin index and the second frequency bin width.

10. The system of claim 9, wherein the Fourier transform representation is a first Fourier transform representation;
wherein the first frequency bin width signal indicates a first number of the samples to be included in determining one or more second Fourier transform representations of the second part of the samples; and
wherein the second frequency bin width signal indicates a second number of the samples to be included in determining the first Fourier transform representation of the first part of the samples.

11. The system of claim 9, wherein the Fourier transform representation is a first Fourier transform representation;
wherein the first frequency bin width signal indicates a first sampling frequency at which the ADC samples the first signal to generate the second part of the samples; and
wherein the second frequency bin width signal indicates a second sampling frequency at which the ADC samples the first signal to generate the first part of the samples.

12. The system of claim 9, wherein the Fourier transform representation is a first Fourier transform representation, and the processing circuit is configured to:
determine a second Fourier transform representation of a first subset of the second part of the samples at a frequency bin having the first frequency bin index and the first frequency bin width;
determine a first phase of the second Fourier transform representation;
determine a third Fourier transform representation of a second subset of the second part of the samples at the frequency bin;
determine a second phase of the third Fourier transform representation; and
determine a difference between the first and second phases;
determine the frequency bin index offset based on the difference and the second frequency bin index.

13. The system of claim 12, wherein the first subset of second part of the samples is in a first time window, the second subset of the second part of the samples is in a second time window next to the first time window.

14. The system of claim 12, wherein the processing circuit is configured to iteratively determine the frequency bin index offset by progressively reducing the first frequency bin width and updating the first frequency bin index.

15. A method comprising:
sampling a first signal at a sampling frequency;
providing a second signal representing samples of the first signal;
providing a third signal as a Fourier transform representation of a part of the samples based on states of a frequency bin width input and a frequency bin index input, wherein the at least the part of the samples is a first part of the samples;
receiving a first frequency bin width signal indicating a first frequency bin width;
receiving a second frequency bin width signal indicating a second frequency bin width;
receiving a first frequency bin index signal indicating a first frequency bin index;
receiving a second frequency bin index signal indicating a second frequency bin index;
determining a frequency bin index offset based on the first frequency bin width signal, the first frequency bin index signal, and a second part of the samples;
determining a corrected frequency bin index based on the second frequency bin index and the frequency bin index offset; and
providing the third signal as the Fourier transform representation of the first part of the samples at a frequency bin having the corrected frequency bin index and the second frequency bin width.

16. The method of claim 15, wherein the Fourier transform representation is a first Fourier transform representation;
wherein the first frequency bin width signal indicates a first number of the samples to be included in determining one or more second Fourier transform representations of the second part of the samples; and
wherein the second frequency bin width signal indicates a second number of the samples to be included in determining the first Fourier transform representation of the first part of the samples.

17. The method of claim 15, wherein the Fourier transform representation is a first Fourier transform representation;
wherein the first frequency bin width signal indicates a first sampling frequency at which an analog to digital (ADC) samples the first signal to generate the second part of the samples; and
wherein the second frequency bin width signal indicates a second sampling frequency at which the ADC samples the first signal to generate the first part of the samples.

18. The method of claim 15, wherein the Fourier transform representation is a first Fourier transform representation, and wherein the method further comprises:
determining a second Fourier transform representation of a first subset of the second part of the samples at a frequency bin having the first frequency bin index and the first frequency bin width;
determining a first phase of the second Fourier transform representation;
determining a third Fourier transform representation of a second subset of the second part of the samples at the frequency bin;
determining a second phase of the third Fourier transform representation;
determining a difference between the first and second phases; and
determining the frequency bin index offset based on the difference and the second frequency bin index.

19. The method of claim 18, wherein the first subset of second part of the samples is in a first time window, the second subset of the second part of the samples is in a second time window next to the first time window, and wherein the method further comprises: iteratively determining the frequency bin offset by progressively reducing the first frequency bin width and updating the first frequency bin index.

20. The method of claim 18 further comprising iteratively determining the frequency bin index offset by progressively reducing the first frequency bin width and updating the first frequency bin index.
